(19) United States
(12) Patent Application Publication
(10) Pub. No.: US 2023/0029248 A1
(43) Pub. Date: Jan. 26, 2023

(54) CHIP MODULE AND METHOD FOR FORMING A CHIP MODULE

(71) Applicant: Infineon Technologies AG, Neubiberg (DE)

(72) Inventors: Frank Pueschner, Kelheim (DE); Thomas Spoettl, Mintraching (DE)

(21) Appl. No.: 17/866,788

(22) Filed: Jul. 18, 2022

(30) Foreign Application Priority Data
Jul. 20, 2021 (DE) 102021118722.2

(51) Int. Cl. G06K 19/077

(52) U.S. Cl. CPC G06K 19/07728; G06K 19/07743

(57) ABSTRACT

A chip module having a chip coupled to at least one electrically conductive region including a metal, and a coating of the at least one electrically conductive region with a layer of at least one organic silicon compound and/or a form of carbon in a thickness having an electrical surface contact resistance of not more than 500 mΩ according to ISO 7810 in a measurement in accordance with ISO 10373-1.

### TECHNICAL FIELD

The disclosure relates to a chip module and to a method of forming a chip module.

### BACKGROUND

In contact-based chip cards, the contact-based chip module integrated therein has typically been equipped with electrically conductive contact surfaces.

The contact surfaces are currently frequently coated with gold (Au) and/or palladium (Pd) in order to protect the chip module from corrosion and/or scratching.

But precious metals (Au, Pd) on such contact surfaces are actually a waste of money, and making the layers thinner (at present, for example, a thickness of 0.03 μm is typically used) is not a solution because protection from corrosion and scratching in that case will possibly be difficult to ensure.

Accordingly, it may be desirable, rather than the precious metal, to use different metals for coating of the contact surfaces, for example a coating with a CuSnZn alloy.

### SUMMARY

The CuSnZn coating is currently provided with an organic surface coating for protection. In particular fields of application, however, there are limits to the protective action of the organic surface coating, especially in the case of a yellow CuSnZn coating that is used as a gold substitute and has a high copper content, and/or in the case of surfaces that are sensitive to fingerprints, for example surfaces that have a colored appearance through exploitation of light diffraction principles.

In various working examples, a chip module having an electrically conductive region (for example a nonprecious metal contact surface) is provided, which is reliably protected from scratching and nevertheless has such a low surface contact resistance that the provisions in this regard in ISO 7810 or ISO 10373-1 are satisfied. In particular, the surface contact resistance may be not more than 500 μm (in accordance with the demands of ISO 7810, in a measurement according to the provisions of ISO 10373-1).

In various working examples, in the chip module, the electrically conductive region may have been coated with a layer of at least one organic silicon compound and/or a form of carbon, where the thickness is chosen (especially sufficiently thinly) such that the surface contact resistance meets the requirements of ISO 7810 or ISO 10373-1, i.e. is low enough (not more than 500 μm).

For attainment of the low surface contact resistance, it may be helpful in various working examples when an Rz surface roughness of the electrically conductive region is within a range from about 0.1 to about 6 μm.

In various working examples, the coating may be dielectric, for example in the utilization of the organic silicon compounds, and robust enough to protect the surface from damage by outside influences. At the same time, however, the coating may be thin enough in order, in spite of its actually dielectric properties, to provide sufficient conductivity (for example for contact-based communication with a reader device).

Working examples of the disclosure are shown in the figures and are elucidated in detail hereinafter.

### BRIEF DESCRIPTION OF THE FIGURES

The figures show:

FIG. 1 a schematic cross-sectional view of a chip module (integrated into a chip card as overview, and as detail enlargement) in various working examples during contact-based operation;

FIG. 2 an illustration of a coating of the chip module in various working examples; and

FIG. 3 a flow diagram of a method of forming a chip module in various working examples.

### DETAILED DESCRIPTION

The detailed description that follows refers to the appended drawings, which form part thereof and which show, by way of illustration, specific embodiments in which the disclosure may be executed. In this regard, directional terminology, for instance “top”, “bottom”, “front”, “back”, “anterior”, “posterior”, etc., is used with reference to the orientation of the figure(s) described. Since components of embodiments may be positioned in a number of different orientations, the directional terminology serves for illustration and is not restrictive in any way at all. It will be apparent that other embodiments may be utilized and structural or logical changes may be made without departing from the scope of protection of the present disclosure. It will be apparent that the features of the various illustrative embodiments described herein may be combined with one another, unless specifically stated otherwise. The detailed description that follows should therefore not be considered in a restrictive manner, and the scope of protection of the present disclosure is defined by the appended claims.

In the context of this description, the terms “joined”, “connected” and “coupled” are used to describe either a direct or indirect join, a direct or indirect connection, and a direct or indirect coupling. In the figures, identical or similar elements are given identical reference numerals, where appropriate.

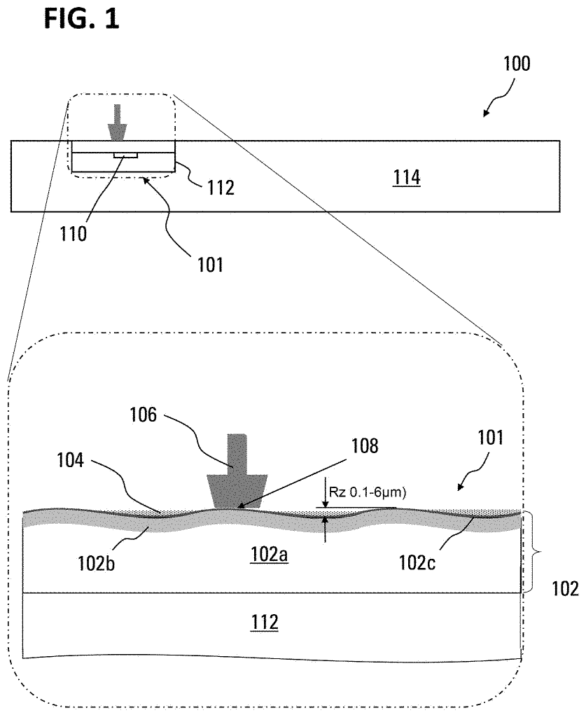

FIG. 1 shows, at the top, a schematic cross-sectional view of a chip card 100 with a chip module 101 integrated into a chip card body 114 in various working examples, which has an exposed electrically conductive region 102 for contact-based operation (also referred to as contact area(s) 102). The diagram shows the chip card 100 or chip module 101 during contact-based operation, i.e. while a portion of a reader device is in contact with the electrically conductive region.

The chip card 100 may take the form of a pure contact-based chip card, or, for example, of a dual-interface chip card set up both for contact-based operation and for contactless operation.

FIG. 1, at the bottom, shows a detail enlargement of the upper diagram (the chip 110 is omitted at the bottom for the sake of clarity), which more particularly shows a working example for the exposed electrically conductive region 102 and the coating thereof.

The chip module 101 may have a chip 110, for example a semiconductor chip, e.g. a chip 110 set up for a typical chip card application, for example payment operations or the like.

The chip 110 may be coupled, for example in a manner essentially known to the person skilled in the art, to the at least one electrically conductive region 102 comprising a metal. The metal may, for example, be a nonprecious metal, since it is thus possible to optimize a cost saving by virtue of the protective layer. Alternatively, in various working examples, precious metals may also be provided with the coating if appropriate to the purpose, since it is thus possible, for example, to enable formation of a thinner precious metal layer.

The electrically conductive region 102 may be formed from a single metal, a layer stack of different metals, or a metal alloy. The metal of the electrically conductive region may, for example, comprise or consist of a copper-tin-zinc alloy, gold, palladium, copper, nickel, copper-nickel or an alloy of the abovementioned metals.

In FIG. 1, the electrically conductive region 102 is formed by way of example from a layer stack of three metal layers: a (copper) carrier layer 102a that may have a thickness, for example, within a range from about 13 μm to about 35 μm, atop the carrier layer 102a a (nickel) interlayer 102b that may have a thickness of about 1 μm to about 2 μm, and atop the interlayer 102b an outer layer 102c that may comprise, for example, gold, palladium or a copper-tin-zinc alloy. The outer layer 102c may have a thickness, for example, within a range from 30 nm to 300 nm.

The electrically conductive region 102, in various working examples, may be formed on a carrier material 112, for example a carrier ribbon typically utilized in the production of chip modules, which may be formed, for example, from polyimide, polyethylene terephthalate (PET) or an epoxy material. A typical thickness of the carrier material 112 may be within a range from about 25 μm to about 200 μm.

The chip module 101 may also have a coating of the at least one electrically conductive region 102 with a layer 104 of at least one organic silicon compound and/or a form of carbon in a thickness having an electrical surface contact resistance of not more than 500 mΩ according to ISO 7810 (in a measurement in accordance with ISO 10373-1).

This means that, especially in the case of use of the organic silicon compound for layer 104, an actually dielectric material is applied so thinly, for example with a layer thickness within a range from around 10 nm to around 200 nm, for example between about 20 nm and about 100 nm, for example between about 20 nm and about 50 nm, that the surface contact resistance is nevertheless small enough to enable contact-based communication by means of the electrically conductive region 102.

The at least one electrically conductive region may, in various working examples, have an Rz surface roughness within a range from around 0.1 to around 6 μm, for example between about 0.5 μm and 3 μm. As illustrated in FIG. 1, the effect may be, for example, that the thickness of the layer 104 is slightly nonuniform, such that an electrical resistance between the reader device and the electrically conductive region 104 is reduced, for example, in the region of an elevation.

“Organic silicon compound”, also referred to as organosilicon compound, is a collective term for compounds that either have direct silicon-carbon bonds (Si—C) or in which the carbon is joined to the silicon via oxygen, nitrogen or sulfur atoms. Organosilicon compounds may be described by the general formula RₙSiX₄₋ₙ (with n from 1 to 4) where R represents various organic radicals, for example aliphatic compounds, aromatic compounds, heterocycles, and X represents various groups, e.g. OH, Si—O, Si—N, Si—C, Cl, H, etc.

Examples of organic silicon compounds usable for the layer 104 are organosilane, organosilanol, organochlorosilane, siloxane, silicone, polysilazane and carbosilane.

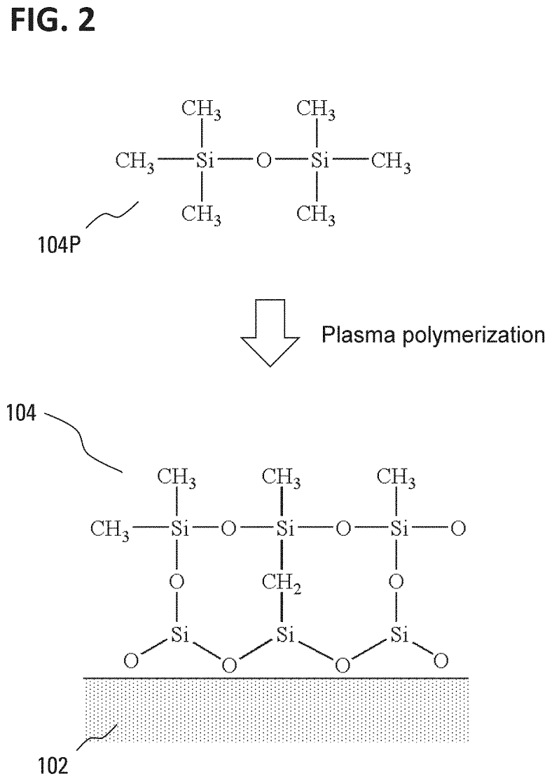

FIG. 2 illustrates the coating of the chip module 101, or of the electrically conductive region 102, with the layer 104 comprising one of the organic silicon compounds, in various working examples.

The organic silicon compound in FIG. 2, which is used for formation of the layer 104 is hexamethyldisiloxane (HMDSO). This forms the precursor which is applied by means of plasma polymerization onto the electrically conductive region 102 and crosslinked.

In general, coating processes for coating the electrically conductive region 102 with the layer 104 may comprise, for example, free jet plasma coating (which is also referred to as open-air plasma coating), chemical gas phase deposition, hot wire-activated gas phase deposition and physical gas phase deposition. Free jet plasma coating may be advantageous in that a free jet plasma system is sometimes already used in the chip module production process for cleaning of the chip module carrier 112 and is thus easily usable additionally for coating.

In various working examples in which the layer 104 includes the form of carbon, the form of carbon may possibly have electrical conductivity so high that both the layer thickness of the layer 104 formed from the form of carbon and the surface roughness of the electrically conductive region 102 are irrelevant or of minor importance for the dimensions of the layer 104.

The at least one form of carbon in the layer 104 may, for example, comprise or consist of amorphous carbon (which is also referred to as diamond-like carbon (DLC) and may be electrically conductive or electrically insulating according to the deposition conditions), (for example deposited) diamond, graphene and/or graphite.

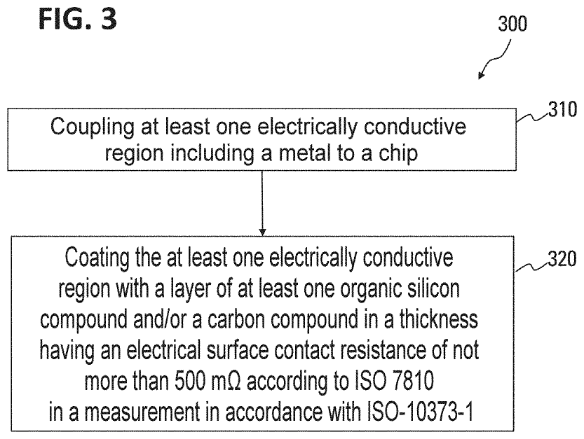

FIG. 3 shows a flow diagram 300 of a method of forming a chip module in various working examples.

The method comprises coupling of at least one electrically conductive region comprising a metal to a chip (310), and coating of the at least one electrically conductive region with a layer of at least one organic silicon compound and/or a form of carbon in a thickness having an electrical contact resistance of not more than 500 mΩ according to ISO 7810 in a measurement in accordance with ISO 10373-1 (320).

Some working examples are summarized hereinafter.

Working example 1 is a chip module. The chip module has a chip coupled to at least one electrically conductive region comprising a metal, and a coating of the at least one electrically conductive region with a layer of at least one organic silicon compound and/or a form of carbon in a thickness having an electrical contact surface resistance of not more than 500 mΩ according to ISO 7810 in a measurement in accordance with ISO 10373-1.

Working example 2 is a chip module according to working example 1, wherein the at least one electrically conductive region has an Rz surface roughness within a range from about 0.1 to about 6 μm.

Working example 3 is a chip module according to working example 1 or 2, wherein the layer has a layer thickness within a range from about 10 nm to about 200 nm.

Working example 4 is a chip module according to any of working examples 1 to 3, wherein the layer has been manufactured by means of a coating process from a group of coating processes comprising free jet plasma coating, chemical gas phase deposition, hot wire-activated gas phase deposition and physical gas phase deposition.

Working example 5 is a chip module according to any of working examples 1 to 4, wherein the at least one organic silicon compound includes at least one bond selected from a group consisting of Si—O, Si—N, Si—C, Si—OH and Si—H.

Working example 6 is a chip module according to any of working examples 1 to 5, wherein the at least one organic silicon compound includes at least one compound selected from a group consisting of organosilane, organosilanol, organochlorosilane, siloxane, silicone, polysilazane and carbosilane.

Working example 7 is a chip module according to any of working examples 1 to 6, wherein the at least one form of carbon includes at least one form selected from a group consisting of amorphous carbon, diamond, graphene and graphite.

Working example 8 is a chip module according to any of working examples 1 to 7, wherein the metal includes at least one metal selected from a group consisting of copper-tin-zinc, gold, palladium, copper, nickel, copper-nickel and an alloy of the abovementioned metals.

Working example 9 is a method of forming a chip module. The method comprises coupling at least one electrically conductive region including a metal to a chip, and coating the at least one electrically conductive region with a layer of at least one organic silicon compound and/or a form of carbon in a thickness having an electrical surface contact resistance of not more than 500 mΩ according to ISO 7810 in a measurement in accordance with ISO 10373-1.

Working example 10 is a method according to working example 9, wherein the at least one electrically conductive region has an Rz surface roughness within a range from about 0.1 to about 6 μm.

Working example 11 is a method according to working example 9 or 10, wherein the layer has a layer thickness within a range from about 10 nm to about 200 nm.

Working example 12 is a method according to any of working examples 9 to 11, wherein the coating comprises at least one from a group of coating methods comprising free jet plasma coating, chemical gas phase deposition, hot wire-activated gas phase deposition and physical gas phase deposition.

Working example 13 is a method according to any of working examples 9 to 12, wherein the at least one organic silicon compound includes at least one bond selected from a group consisting of Si—O, Si—N, Si—C, Si—OH and Si—H.

Working example 14 is a method according to any of working examples 9 to 13, wherein the at least one organic silicon compound includes at least one compound selected from a group consisting of organosilane, organosilanol, organochlorosilane, siloxane, silicone, polysilazane and carbosilane.

Working example 15 is a method according to any of working examples 9 to 14, wherein the at least one form of carbon includes at least one compound selected from a group consisting of amorphous carbon, diamond, graphene and graphite.

Working example 16 is a method according to any of working examples 9 to 15, wherein the metal includes at least one metal selected from a group consisting of copper-tin-zinc, gold, palladium, copper, nickel, copper-nickel and an alloy of the abovementioned metals.

Further advantageous configurations of the device will be apparent from the description of the method and vice versa.

1. A chip module, comprising:
a chip coupled to at least one electrically conductive region comprising a metal; and
a coating of the at least one electrically conductive region with a layer of at least one organic silicon compound and/or a form of carbon in a thickness having an electrical surface contact resistance of not more than 500 mΩ according to ISO 7810 in a measurement in accordance with ISO 10373-1.

2. The chip module as claimed in claim 1,
wherein the at least one electrically conductive region has an Rz surface roughness within a range from about 0.1 to about 6 μm.

3. The chip module as claimed in claim 1,
wherein the layer has a layer thickness within a range from about 10 nm to about 200 nm.

4. The chip module as claimed in claim 1,
wherein the layer has been manufactured by a coating process selected from a group of coating processes consisting of: free jet plasma coating, chemical gas phase deposition, hot wire-activated gas phase deposition, and physical gas phase deposition.

5. The chip module as claimed in claim 1,
wherein the at least one organic silicon compound comprises at least one bond selected from a group of bonds consisting of: Si—O, Si—N, Si—C, Si—OH, and Si—H.

6. The chip module as claimed in claim 1,
wherein the at least one organic silicon compound includes at least one compound selected from a group of compounds consisting of: organosilane, organosilanol, organochlorosilane, siloxane, silicone, polysilazane, and carbosilane.

7. The chip module as claimed in claim 1, wherein the at least one form of carbon comprises at least one form selected from a group of carbons consisting of: amorphous carbon, diamond, graphene, and graphite.

8. The chip module as claimed in claim 1,
wherein the metal comprises at least one metal selected from a group of metals consisting of: copper-tin-zinc, gold, palladium, copper, nickel, copper-nickel, a copper-tin-zinc alloy, a gold alloy, a palladium alloy, a copper alloy, a nickel alloy, and a copper-nickel alloy.

9. A method of forming a chip module, the method comprising:
coupling at least one electrically conductive region comprising a metal to a chip; and
coating the at least one electrically conductive region with a layer of at least one organic silicon compound and/or a form of carbon in a thickness having an electrical surface contact resistance of not more than 500 mΩ according to ISO 7810 in a measurement in accordance with ISO 10373-1.

10. The method as claimed in claim 9,
wherein the at least one electrically conductive region has an Rz surface roughness within a range from about 0.1 to about 6 μm.

11. The method as claimed in claim 9,
wherein the coating has a layer thickness within a range from about 10 nm to about 200 nm.

12. The method as claimed in claim 9,
wherein the coating comprises at least one coating method selected from a group of coating methods consisting of: free jet plasma coating, chemical gas phase deposition, hot wire-activated gas phase deposition, and physical gas phase deposition.

13. The method as claimed in claim 9,
wherein the at least one organic silicon compound comprises at least one bond selected from a group of bonds consisting of: Si—O, Si—N, Si—C, Si—OH, and Si—H.

14. The method as claimed in claim 9,
wherein the at least one organic silicon compound comprises at least one compound selected from a group of compounds consisting of: organosilane, organosilanol, organochlorosilane, siloxane, silicone, polysilazane, and carbosilane.

15. The method as claimed in claim 9,
wherein the at least one form of carbon comprises at least one form selected from a group of forms consisting of: amorphous carbon, diamond, graphene, and graphite.

16. The method as claimed in claim 9,
wherein the metal comprises at least one metal selected from a group of metals consisting of: copper-tin-zinc, gold, palladium, copper, nickel, copper-nickel, a copper-tin-zinc alloy, a gold alloy, a palladium alloy, a copper alloy, a nickel alloy, and a copper-nickel alloy.
